(19) United States
(12) Patent Application Publication
(10) Pub. No.: US 2025/0374778 A1
(43) Pub. Date: Dec. 4, 2025

(54) DISPLAY DEVICE

(71) Applicant: Samsung Display Co., Ltd., Yongin-Si (KR)

(72) Inventors: Keun Woo KIM, Yongin-si (KR); So Young KOO, Yongin-si (KR); Jong Do KEUM, Yongin-si (KR); Hyoung Do KIM, Yongin-si (KR); Ae Ran SONG, Yongin-si (KR)

(21) Appl. No.: 19/029,335

(22) Filed: Jan. 17, 2025

(30) Foreign Application Priority Data
May 29, 2024 (KR) 10-2024-0070058

(51) Int. Cl. H10K 59/131; G09G 3/3233; H10K 59/121

(52) U.S. Cl. CPC H10K 59/131; H10K 59/1213; G09G 3/3233; G09G 2300/0426; G09G 2300/0819; G09G 2300/0842; G09G 2300/0861; G09G 2320/0233

(57) ABSTRACT

A display device includes a display area including a plurality of pixels, a display driver disposed outside the display area to apply a data voltage, a plurality of data lines for applying the data voltage to the plurality of pixels, and a bridge line electrically connecting some of the data lines with the display driver. The bridge line includes a first bridge line extended from the display driver in a first direction, and a second bridge line connected to the first bridge line and extended in a second direction intersecting the first direction. The second bridge line includes a plurality of first portions extended in the second direction and spaced apart from each other in the second direction, and a second portion disposed on the first portions and electrically connecting the first portions.

### CROSS-REFERENCE TO RELATED APPLICATION

This application claims priority to Korean Patent Application No. 10-2024-0070058 filed on May 29, 2024, and all the benefits accruing therefrom under 35 U.S.C. § 119, the content of which in its entirety is herein incorporated by reference.

### BACKGROUND

### 1. FIELD OF THE DISCLOSURE

The present disclosure relates to a display device.

### 2. DESCRIPTION OF THE RELATED ART

As the information-oriented society evolves, various demands for display devices are ever increasing. For example, display devices are being employed by a variety of electronic devices such as smart phones, digital cameras, laptop computers, navigation devices, and smart televisions. A display device, in which each of the pixels of the display panel includes a light-emitting element that can emit light by itself, can display images without a backlight unit that supplies light to the display panel.

The display device includes a plurality of pixels, data lines and gate lines connected to the plurality of pixels, a data driver that supplies data voltages to the data lines, and a gate driver that supplies gate signals to the gate lines. The data driver and the gate driver may drive the plurality of pixels at a predetermined frequency.

### SUMMARY

Aspects of the present disclosure provide a display device that can prevent a parasitic transistor, so that an initialization voltage can be applied properly and Mura or poor brightness on the display panel can be prevented.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a display area including a plurality of pixels, a display driver disposed outside the display area to apply a data voltage, a plurality of data lines for applying the data voltage to the plurality of pixels, and a bridge line electrically connecting some of the data lines with the display driver. The bridge line includes a first bridge line extended from the display driver in a first direction, and a second bridge line connected to the first bridge line and extended in a second direction intersecting the first direction. The second bridge line includes a plurality of first portions extended in the second direction and spaced apart from each other in the second direction, and a second portion disposed on the first portions and electrically connecting the first portions.

The display device may further include a first initialization voltage line for applying a first initialization voltage to the plurality of pixels. At least one pixel among the plurality of pixels includes a light-emitting element disposed on a substrate, a first transistor configured to control a driving current flowing through the light-emitting element, a second transistor configured to supply a data voltage to a first electrode of the first transistor, a third transistor configured to electrically connect a second electrode of the first transistor with a gate electrode of the first transistor, and a fourth transistor configured to electrically connect the gate electrode of the first transistor with the first initialization voltage line.

A first electrode of the fourth transistor may be electrically connected to the gate electrode of the first transistor, and a second electrode of the fourth transistor may overlap with the second portion of the second bridge line.

The display device may further include a first gate line for supplying a first gate signal to the second transistor, a second gate line for supplying a second gate signal to the third transistor, and a third gate line for supplying a third gate signal to the fourth transistor.

The second portion of the second bridge line may be disposed between the first initialization voltage line and the third gate line.

The second electrode of the fourth transistor may include a protrusion protruding in the second direction. A width of the second portion of the second bridge line in the first direction may be smaller than a width of the protrusion in the first direction.

The second electrode of the fourth transistor may include a protrusion protruding in the second direction. A width of the second portion of the second bridge line in the first direction may be greater than a width of the protrusion in the first direction.

The display device may further include a first active layer including semiconductor regions of the first and second transistors, a first gate layer disposed on the first active layer, a second gate layer disposed on the first gate layer, a second active layer including semiconductor regions of the third and fourth transistors, a third gate layer disposed on the second active layer, a first source metal layer disposed on the third gate layer and including the first portions of the second bridge line, and a second source metal layer disposed on the first source metal layer and including the second portion of the second bridge line.

The display device may further include a driving voltage line for applying a driving voltage to the plurality of pixels, and a second initialization voltage line for applying a second initialization voltage to the plurality of pixels. The at least one pixel further includes a fifth transistor configured to electrically connect the driving voltage line with the first electrode of the first transistor, a sixth transistor configured to electrically connect the second electrode of the first transistor with a first electrode of the light-emitting element, and a seventh transistor configured to electrically connect the first electrode of the light-emitting element with the second initialization voltage line.

The display device may further include a bias voltage line for applying a bias voltage. The at least one pixel further includes: an eighth transistor configured to electrically connect the bias voltage line with the first electrode of the first transistor.

According to an embodiment of the present disclosure, a display device includes first and second pixels each including a light-emitting element, a display driver configured to apply data voltage to the first and second pixels. a first data line connected to the display driver to apply the data voltage to the first pixel, a second data line for apply the data voltage to the second pixel, and a bridge line electrically connecting the display driver and the second data line. The bridge line includes a first bridge line extended from the display driver in a first direction, and a second bridge line connected to the first bridge line and extended in a second direction intersecting the first direction to overlap with the first pixel. The second bridge line includes a plurality of first portions extended in the second direction and spaced apart from each other in the second direction, and a second portion disposed on the first portions and electrically connecting the first portions.

The bridge line may further include a third bridge line connecting the second bridge line and the second data line and extended in the first direction.

The display device may further include a first active layer disposed on a substrate and including a first material, a first gate layer disposed on the first active layer, a second gate layer disposed on the first gate layer, a second active layer disposed on the second gate layer and including a second material different from the first material, a third gate layer disposed on the second active layer, a first source metal layer disposed on the third gate layer and including the first portions of the second bridge line, and a second source metal layer disposed on the first source metal layer and including the second portion of the second bridge line.

The display device may further include a first initialization voltage line for applying a first initialization voltage to the first and second pixels. The first pixel may include a first transistor configured to control a driving current flowing through the light-emitting element, a second transistor electrically connecting a first electrode of the first transistor with the first data line, a third transistor electrically connecting a second electrode of the first transistor with a gate electrode of the first transistor, and a fourth transistor electrically connecting the gate electrode of the first transistor with the first initialization voltage line.

The second portion of the second bridge line may be disposed between the fourth transistor and the first initialization voltage line.

Semiconductor regions of the first and second transistors may be disposed in the first active layer, and semiconductor regions of the third and fourth transistors may be disposed in the second active layer.

The display device may further include a first gate line disposed in the first gate layer to supply a first gate signal to the second transistor, a second gate line disposed in the third gate layer to supply a second gate signal to the third transistor, and a third gate line disposed in the third gate layer to supply a third gate signal to the fourth transistor.

The second portion of the second bridge line may be disposed between the first initialization voltage line and the third gate line.

According to an embodiment of the present disclosure, a display device includes a display driver configured to apply data voltage, first and second data lines extended in a first direction and electrically connected to the display driver, a first initialization voltage line for applying a first initialization voltage, a light-emitting element emitting light, a first transistor configured to control a driving current flowing through the light-emitting element, a second transistor configured to electrically connect the first data line with a first electrode of the first transistor, a third transistor configured to electrically connect a second electrode of the first transistor with a gate electrode of the first transistor, a fourth transistor configured to electrically connect the gate electrode of the first transistor with the first initialization voltage line, a bridge line electrically connecting the display driver with the second data line and overlapping with the fourth transistor. The bridge line includes a plurality of first portions extended in a second direction intersecting the first direction and spaced apart from each other in the second direction, and a second portion disposed on the first portions and electrically connecting between the first portions.

The display device may further include a first active layer including semiconductor regions of the first and second transistors, a first gate layer disposed on the first active layer, a second gate layer disposed on the first gate layer, a second active layer including semiconductor regions of the third and fourth transistors, a third gate layer disposed on the second active layer, a first source metal layer disposed on the third gate layer and including the first portions of the bridge line, and a second source metal layer disposed on the first source metal layer and including the second portion of the bridge line.

According to one or more embodiments, by relatively increasing the distance between a bridge line and an oxide-based active layer in a display device, it is possible to prevent a parasitic transistor so that an initialization voltage can be applied properly and Mura or poor brightness on the display panel can be prevented.

It should be noted that effects of the present disclosure are not limited to those described above and other effects of the present disclosure will be apparent to those skilled in the art from the following descriptions.

### BRIEF DESCRIPTION OF THE DRAWINGS

The above and other features of the inventive concept will become more apparent by describing in detail embodiments thereof with reference to the accompanying drawings.

FIG. 1 is a perspective view showing a display device according to an embodiment of the present disclosure.

FIG. 2 is a cross-sectional view showing a display device according to an embodiment of the present disclosure.

FIG. 3 is a plan view showing a display unit of a display device according to an embodiment of the present disclosure.

FIG. 4 is a block diagram illustrating the display panel and the display driver according to an embodiment.

FIG. 5 is a circuit diagram showing a pixel of a display device according to an embodiment of the present disclosure.

FIG. 6 is a cross-sectional view showing a pixel in a display device according to an embodiment of the present disclosure.

FIG. 7 is a layout diagram showing a part of a pixel according to an embodiment.

FIG. 8 is a cross-sectional view, taken along line I-I′ of FIG. 7.

FIG. 9 is a cross-sectional view, taken along line II-II′ of FIG. 7. FIG. 10 is a layout diagram showing a part of a pixel according to an embodiment.

### DETAILED DESCRIPTION OF THE EMBODIMENTS

Embodiments of the present disclosure address a problem in which any of a plurality of touch lines overlapping data fan-out line or scan fan-out line produce a parasitic capacitance between the touch line and the data fan-out line or between the touch line and the scan fan-out line. Due to the parasitic capacitance, a touch signal of the touch line may be affected by a data voltage of the data fan-out line or a scan control signal of the scan fan-out line, and thus, a touch sensing error may occur.

Embodiments of the present disclosure provide a display device capable of preventing a touch signal of a touch line from being affected by a data voltage of a data fan-out line or a scan control signal of a scan fan-out line.

The present disclosure now will be described more fully hereinafter with reference to the accompanying drawings, in which various embodiments are shown. This present disclosure may, however, be embodied in many different forms, and should not be construed as limited to the embodiments set forth herein. Rather, these embodiments are provided so that this disclosure will be thorough and complete, and will fully convey the scope of the present disclosure to those skilled in the art. Like reference numerals refer to like elements throughout.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” “third” etc. may be used herein to describe various elements, components, regions, layers or sections, these elements, components, regions, layers or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As used herein, the terms “comprises,” “comprising,” “includes,” and “including” mean the presence of stated features, regions, integers, steps, operations, elements, or components, but do not preclude the presence or addition of one or more other features, regions, integers, steps, operations, elements, components, or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

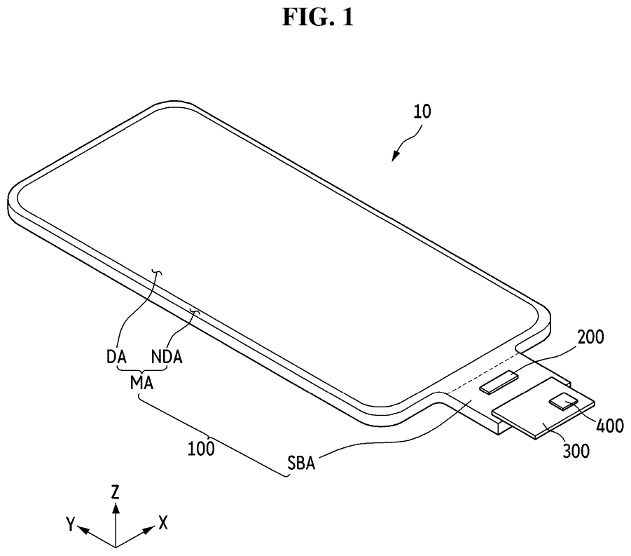

FIG. 1 is a perspective view showing a display device 10 according to an embodiment of the present disclosure.

Referring to FIG. 1, a display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). For another example, the display device 10 may be applied to wearable devices such as a smart watch, a watch phone, a glasses-type display, and a head-mounted display (HMD) device.

The display device 10 may have a shape similarly to a quadrangular shape when viewed from the top. For example, the display device 10 may have a shape similar to a rectangle having shorter sides in the x-axis direction and longer sides in the y-axis direction when viewed from the top. The corners where the shorter sides in the x-axis direction and the longer sides in the y-axis direction meet may be rounded to have a predetermined curvature or may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include a display area DA having pixels for displaying images, and a non-display area NDA located around the display area DA. The display area DA may output lights from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, one of: an organic light-emitting diode including an organic light-emitting layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be located on the outer side of the display area DA. The non-display area NDA may be defined as the edge of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from one side of the main area MA. The subsidiary area SUB may include a flexible material that can be bent, folded, or rolled. For example, when the subsidiary area SBA is bent, the subsidiary area SBA may overlap the main area MA in the thickness direction (z-axis direction). The subsidiary area SBA may include pads connected to the display driver 200 and the circuit board 300. Optionally, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction (z-axis direction) as the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signals may be pulse signals having a predetermined frequency. The touch driver 400 may determine whether there is an input and may find the coordinates of the input based on the amount of the change in the capacitance between the touch electrodes. The touch driver 400 may be implemented as an integrated circuit (IC).

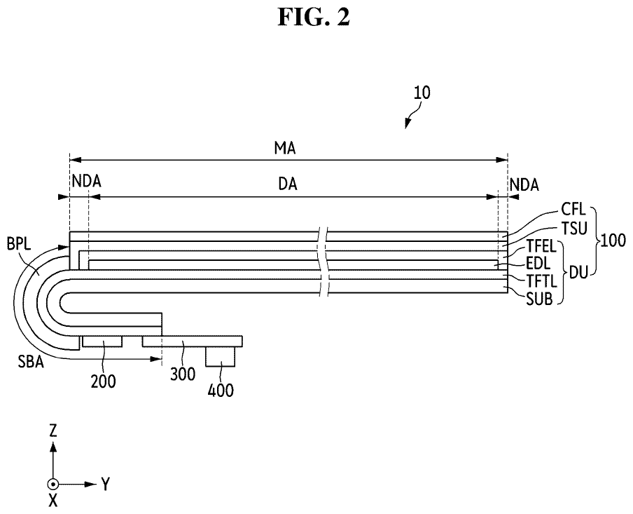

FIG. 2 is a cross-sectional view showing a display device 10 according to an embodiment of the present disclosure.

Referring to FIG. 2, the display panel 100 may include a display unit DU, a touch sensing unit TSU, and a color filter layer CFL. The display unit DU may include a substrate SUB, a transistor layer TFTL, an emission material layer EDL and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The transistor layer TFTL may be disposed on the substrate SUB. The transistor layer TFTL may include a plurality of transistors forming pixel circuits of pixels. The transistor layer TFTL may include gate lines, data lines, voltage lines, gate control lines, fan-out lines for connecting the display driver 200 with the data lines, lead lines for connecting the display driver 200 with the pads, etc. Each of the transistors may include a semiconductor region, a source electrode, a drain electrode, and a gate electrode. For example, when the gate driver is formed on one side of the non-display area NDA of the display panel 100, the gate driver may include transistors.

The transistor layer TFTL may be disposed in the display area DA, the non-display area NDA and the subsidiary area SBA. Transistors, gate lines, data lines and power lines in the transistor layer TFTL for the pixels may be disposed in the display area DA. The gate control lines and the fan-out lines in the transistor layer TFTL may be disposed in the non-display area NDA. The lead lines of the transistor layer TFTL may be disposed in the subsidiary area SBA.

The emission material layer EDL may be disposed on the transistor layer TFTL. The emission material layer EDL may include a plurality of light-emitting elements in each of which a pixel electrode, an emissive layer and a common electrode are stacked on one another sequentially to emit light, and a pixel-defining film for defining the pixels. The plurality of light-emitting elements in the emission material layer EDL may be disposed in the display area DA.

For example, the emissive layer may be an organic light-emitting layer containing an organic material. The emissive layer may include a hole transporting layer, an organic light-emitting layer and an electron transporting layer. When the pixel electrode receives a voltage and the common electrode receives a cathode voltage through the transistor in the transistor layer TFTL, holes may move to the organic light-emitting layer through the hole transporting layer, and electrons may move to the organic light-emitting layer through the electron transporting layer, such that they combine in the organic light-emitting layer to emit light. For example, the pixel electrode may be an anode electrode while the common electrode may be a cathode electrode. It is, however, to be understood that the present disclosure is not limited thereto.

As another example, the light-emitting elements may include quantum-dot light-emitting diodes each including a quantum-dot emissive layer, inorganic light-emitting diodes each including an inorganic semiconductor, or micro light-emitting diodes.

The encapsulation layer TFEL may cover the upper and side surfaces of the emission material layer EDL, and can protect the emission material layer EDL. The encapsulation layer TFEL may include at least one inorganic layer and at least one organic layer for encapsulating the emission material layer EDL.

The touch sensing unit TSU may be disposed on the encapsulation layer TFEL. The touch sensing unit TSU may include a plurality of touch electrodes for sensing a user's touch by capacitive sensing, and touch lines connecting the touch electrodes with the touch driver 400. For example, the touch sensing unit TSU may sense a user's touch by mutual capacitance sensing or self-capacitance sensing.

For another example, the touch sensing unit TSU may be disposed on a separate substrate disposed on the display unit DU. In such case, the substrate supporting the touch sensing unit TSU may be an encapsulation substrate that encapsulates the display unit DU.

The plurality of touch electrodes of the touch sensing unit TSU may be disposed in a touch sensor area overlapping with the display area DA. The touch lines of the touch sensing unit TSU may be disposed in a touch peripheral area overlapping with the non-display area NDA.

The color filter layer CFL may be disposed on the touch sensing unit TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensing unit TSU, the display device 10 may require no separate substrate for the color filter layer CFL. Therefore, the thickness of the display device 10 can be relatively reduced.

The subsidiary area SBA of the display panel 100 may be extended from one side of the main area MA. The subsidiary area SUB may include a flexible material that can be bent, folded, or rolled. For example, when the subsidiary area SBA is bent, the subsidiary area SBA may overlap the main area MA in the thickness direction (z-axis direction). The subsidiary area SBA may include pads electrically connected to the display driver 200 and the circuit board 300.

The display device 10 may include a bending protection layer BPL that protects the subsidiary area SBA. The bending protection layer BPL may be disposed on the transistor layer TFTL of the bent subsidiary area SBA. The bending protection layer BPL may protect the transistor layer TFTL of the bent subsidiary area SBA and reduce tensile stress of the subsidiary area SBA.

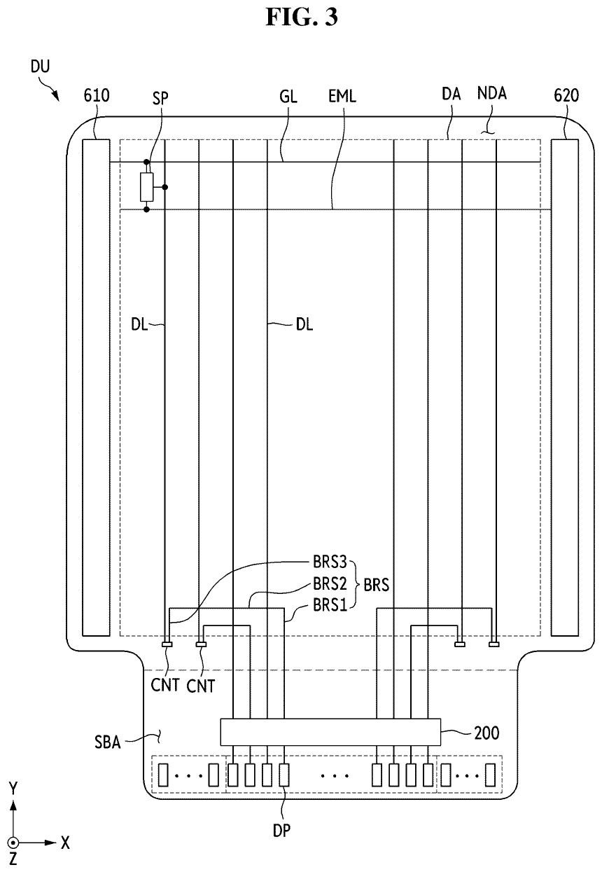

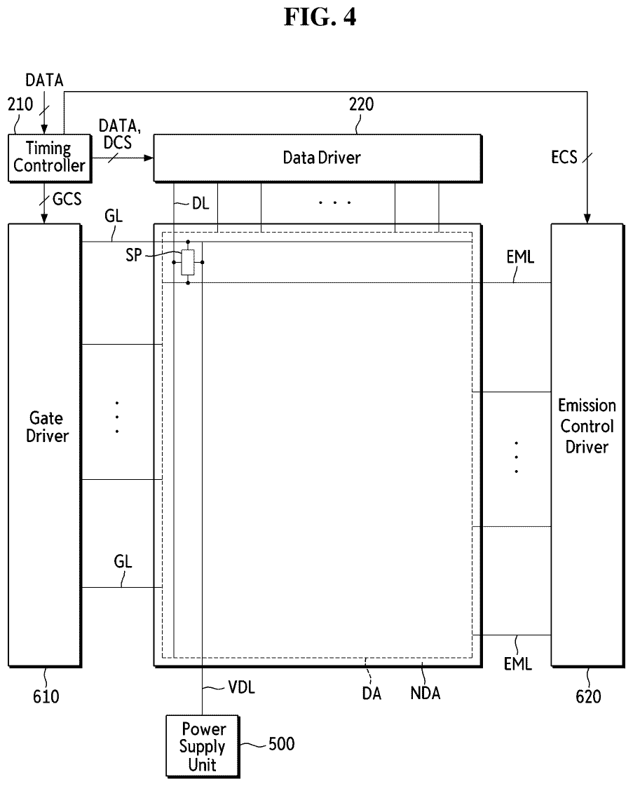

FIG. 3 is a plan view showing the display unit DU of the display device 10 according to the embodiment of the present disclosure. FIG. 4 is a block diagram illustrating the display panel 100 and the display driver 200 according to an embodiment.

Referring to FIGS. 3 and 4, the display panel 100 may include the display area DA and the non-display area NDA. The display area DA may include pixels SP, gate lines GL, emission control lines EML, data lines DL, and bridge lines BRS.

Each of the plurality of pixels SP may be connected to a gate line GL, a data line DL, and an emission control line EML. Each of the plurality of pixels SP may include at least one transistor, a light-emitting element, and a capacitor.

The gate lines GL may be extended in the x-axis direction and may be spaced apart from one another in the y-axis direction crossing the x-axis direction. The gate lines GL may sequentially supply gate signals to the plurality of pixels SP.

The emission control lines EML may be extended in the x-axis direction and may be spaced apart from each other in the y-axis direction. The emission control lines EML may sequentially supply emission signals to the pixels SP.

The data lines DL may be extended in the y-axis direction and may be spaced apart from one another in the x-axis direction. Some of the data lines DL may be electrically connected to the display driver 200 through the bridge lines BRS, and some other data lines DL may be connected directly to the display driver 200. The data lines DL may supply data voltages to the pixels SP. The data voltage may determine the brightness of each of the plurality of pixels SP.

The bridge lines BRS may electrically connect the display driver 200 with the data lines DL. The bridge lines BRS may supply the data voltage received from the display driver 200 to some of the data lines DL.

The bridge lines BRS may include first to third bridge lines BRS1, BRS2, and BRS3. The first bridge line BRS1 may be extended in the y-axis direction from the display driver 200 to the display area DA. The second bridge line BRS2 may be extended from the first bridge line BRS1 in the x-axis direction or in the direction opposite to the x-axis direction. The third bridge line BRS3 may be extended in the direction opposite to the y-axis direction from the second bridge line BRS2. The third bridge line BRS3 may be electrically connected to a data line DL through a contact portion CNT. Accordingly, as the display device 10 includes the bridge lines BRS, the fan-out lines extended diagonally from the display driver 200 to the display area DA can be eliminated, and the lower portion of the non-display area NDA can be reduced.

Optionally, the third bridge line BRS3 may be eliminated. In this instance, the second bridge line BRS2 may directly supply the data voltage to the data lines DL.

The non-display area NDA may surround the display area DA. The non-display area NDA may include a gate driver 610, and an emission control driver 620.

The subsidiary area SBA may be extended from one side of the non-display area NDA. The subsidiary area SBA may include the display driver 200 and pads DP. The pads DP may be disposed closer to one edge of the subsidiary area SBA than the display driver 200. The pads DP may be electrically connected to the circuit board 300 through an anisotropic conductive film.

The display driver 200 may include a timing controller 210 and a data driver 220.

The timing controller 210 may receive digital video data DATA and timing signals from the circuit board 300. The timing controller 210 may generate a data control signal DCS based on timing signals and may provide digital video data DATA and the data control signal DCS to the data driver 220, thereby controlling the operation timing of the data driver 220. The timing controller 210 may control the operation timing of the gate driver 610 by generating a gate control signal GCS based on the timing signals to supply it to the gate driver 610. The timing controller 210 may control the operation timing of the emission control driver 620 by generating an emission control signal ECS based on the timing signals to supply it to the emission control driver 620.

The data driver 220 may convert the digital video data DATA into analog data voltages and may supply them to the data lines DL. The gate signals of the gate driver 610 may be used to select pixels SP to which data voltages are applied, and the selected pixels SP may receive the data voltages through the data lines DL.

A power supply unit 500 may apply supply voltages to the display driver 200 and the display panel 100. The power supply unit 500 may generate a driving voltage to supply it to a driving voltage line VDL, and may generate a common voltage to supply it to a common electrode shared by the light-emitting elements of a plurality of pixels SP. The power supply unit 500 may generate an initialization voltage to supply it to the initialization voltage line, may generate a reference voltage to supply it to a reference voltage line, and may generate a bias voltage to supply it to a bias voltage line.

The gate driver 610 may be disposed on one outer side of the display area DA or on one outer side of the non-display area NDA, and the emission control driver 620 may be disposed on an opposite outer side of the display area DA or on an opposite outer side of the non-display area NDA. It should be understood, however, that the present disclosure is not limited thereto. For another example, the gate driver 610 and the emission control driver 620 may be disposed on one side or an opposite side of the non-display area NDA.

The gate driver 610 may include a plurality of thin-film transistors for generating gate signals based on the gate control signal GCS. The emission control driver 620 may include a plurality of thin-film transistors for generating emission signals based on the emission control signal ECS. For example, the transistors of the gate driver 610 and the transistors of the emission control driver 620 may be formed in the same layer as the transistors of each of the pixels SP. The gate driver 610 may provide gate signals to the gate lines GL, and the emission control driver 620 may provide emission signals to the emission control lines EML.

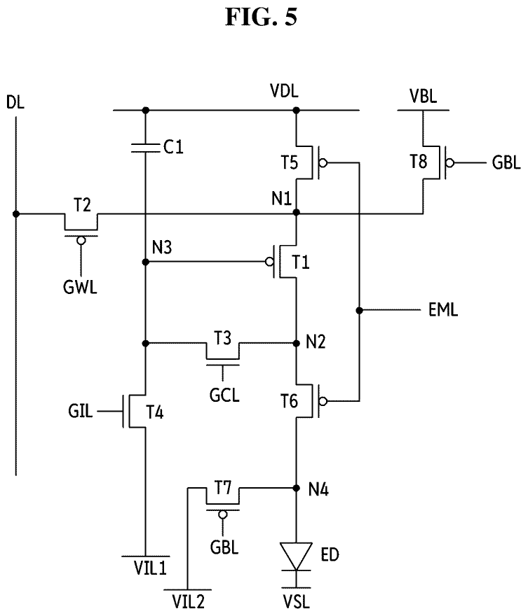

FIG. 5 is a circuit diagram showing a pixel SP of a display device according to an embodiment of the present disclosure.

Referring to FIG. 5, the display panel 100 may include a plurality of pixels SP arranged in rows and columns. Each of the plurality of pixels SP may be connected to a first gate line GWL, a second gate line GCL, a third gate line GIL, a fourth gate line GBL, an emission control line EML, a data line DL, a supply voltage line VDL, a first initialization voltage line VIL1, a second initialization voltage line VIL2, a bias voltage line VBL, and a low-level voltage line VSL.

The pixel SP may include a light-emitting element ED and a pixel circuit that drives the light-emitting element ED. The pixel circuit may include first to eighth transistors T1, T2, T3, T4, T5, T6, T7 and T8, and a first capacitors C1.

The first transistor T1 may control a driving current supplied to the light-emitting element ED. The first transistor T1 may include a gate electrode, a first electrode, and a second electrode. The gate electrode of the first transistor T1 may be connected to a third node N3, the first electrode thereof may be connected to a first node N1, and the second electrode thereof may be connected to a second node N2. For example, the first electrode of the first transistor T1 may be the source electrode while the second electrode may be the drain electrode. It is, however, to be understood that the present disclosure is not limited thereto.

The first transistor T1 may control the source-drain current Isd (hereinafter, referred to as “driving current”) according to the data voltage applied to the gate electrode. The driving current Isd flowing through the channel of the first transistor T1 may be proportional to the square of the difference between the threshold voltage Vth and the voltage Vsg between the source electrode and the gate electrode of the first transistor T1 (Isd=k×(Vsg−Vth)²), where k denotes a proportional coefficient determined by the structure and physical properties of the first transistor T1, Vsg denotes the source-gate voltage of the first transistor T1, and Vth denotes the threshold voltage of the first transistor T1.

The light-emitting element ED may receive the driving current Isd to emit light. The amount or the luminance of the light emitted from the light-emitting element ED may be proportional to the magnitude of the driving current Isd. The light-emitting element ED may include a first electrode, a second electrode, and an emissive layer disposed between the first electrode and the second electrode. The first electrode of the light-emitting element ED may be connected to a fourth node N4. The first electrode of the light-emitting element ED may be electrically connected to the second electrode of the sixth transistor T6 and the first electrode of the seventh transistor T7 through the fourth node N4. The second electrode of the light-emitting element ED may be electrically connected to the low-level voltage line VSL and may receive a low-level voltage from the low-level voltage line VSL. For example, the first electrode of the light-emitting element ED may be an anode electrode or a pixel electrode, while the second electrode thereof may be a cathode electrode or a common electrode. It is, however, to be understood that the present disclosure is not limited thereto.

The second transistor T2 may be turned on by a first gate signal of the first gate line GWL to electrically connect the data line DL with the first node N1, which is the first electrode of the first transistor T1. The second transistor T2 may be turned on in response to the first gate signal to apply data voltage to the first node N1. The gate electrode of the second transistor T2 may be connected to the first gate line GWL, the first electrode thereof may be connected to the data line DL, and the second electrode thereof may be connected to the first node N1. The second electrode of the second transistor T2 may be electrically connected to the first electrode of the first transistor T1, the second electrode of the fifth transistor T5 and the second electrode of the eighth transistor T8 through the first node N1. For example, the first electrode of the second transistor T2 may be the source electrode while the second electrode may be the drain electrode. It is, however, to be understood that the present disclosure is not limited thereto.

The third transistor T3 may be turned on by a second gate signal of the second gate line GCL and may electrically connect the second node N2 which is the second electrode of the first transistor T1 with the third node N3 which is the gate electrode of the first transistor T1. The gate electrode of the third transistor T3 may be connected to the second gate line GCL, the first electrode thereof may be connected to the second node N2, and the second electrode thereof may be connected to the third node N3. The first electrode of the third transistor T3 may be electrically connected to the second electrode of the first transistor T1 and the first electrode of the sixth transistor T6 through the second node N2. The second electrode of the third transistor T3 may be electrically connected to the gate electrode of the first transistor T1, the first electrode of the fourth transistor T4, and the first capacitor electrode of the capacitor C1 through the third node N3. For example, the first electrode of the third transistor T3 may be the drain electrode while the second electrode may be the source electrode. It is, however, to be understood that the present disclosure is not limited thereto.

The fourth transistor T4 may be turned on by a third gate signal of the third gate line GIL to electrically connect the third node N3 which is the gate electrode of the first transistor T1 with the first initialization voltage line VIL1. As the fourth transistor T4 is turned on based on a third gate signal, the gate electrode of the first transistor T1 may be initialized to the first initialization voltage. The gate electrode of the fourth transistor T4 may be connected to the third gate line GIL, the first electrode thereof may be connected to the third node N3, and the second electrode thereof may be connected to the first initialization voltage line VIL1. The first electrode of the fourth transistor T4 may be electrically connected to the gate electrode of the first transistor T1, the second electrode of the third transistor T3, and the first capacitor electrode of the capacitor C1 through the third node N3. For example, the first electrode of the fourth transistor T4 may be the drain electrode while the second electrode may be the source electrode. It is, however, to be understood that the present disclosure is not limited thereto.

The fifth transistor T5 may be turned on by an emission signal of the emission control line EML and may electrically connect the driving voltage line VDL with the first node N1 which is the first electrode of the first transistor T1. A gate electrode of the fifth transistor T5 may be connected to the emission control line EML, a first electrode thereof may be connected to the supply voltage line VDL, and a second electrode thereof may be connected to the first node N1. The second electrode of the fifth transistor T5 may be electrically connected to the first electrode of the first transistor T1, the second electrode of the second transistor T2 and the second electrode of the eighth transistor T8 through the first node N1. For example, the first electrode of the fifth transistor T5 may be the source electrode while the second electrode may be the drain electrode. It is, however, to be understood that the present disclosure is not limited thereto.

The sixth transistor T6 may be turned on by the emission signal of the emission control line EML to electrically connect the second node N2 which is the second electrode of the first transistor T1 with the fourth node N4 which is the first electrode of the light-emitting element ED. The gate electrode of the sixth transistor T6 may be connected to the emission control line EML, the first electrode thereof may be connected to the second node N2, and the second electrode thereof may be connected to the fourth node N4. The first electrode of the sixth transistor T6 may be electrically connected to the second electrode of the first transistor T1 and the first electrode of the third transistor T3 through the second node N2. The second electrode of the sixth transistor T6 may be electrically connected to the first electrode of the light-emitting element ED and the first electrode of the seventh transistor T7 through the fourth node N4. For example, the first electrode of the sixth transistor T6 may be the source electrode while the second electrode may be the drain electrode. It is, however, to be understood that the present disclosure is not limited thereto.

When all of the fifth transistor T5, the first transistor T1 and the sixth transistor T6 are turned on, the driving current Isd may be supplied to the light-emitting element ED.

The seventh transistor T7 may be turned on by a fourth gate signal of the fourth gate line GBL to electrically connect the second initialization voltage line VIL2 with the fourth node N4 which is the first electrode of the light-emitting element ED. As the seventh transistor T7 is turned on based on the fourth gate signal, the first electrode of the light-emitting element ED may be initialized to the second initialization voltage. The second initialization voltage of the second initialization voltage line VIL2 may be different from the first initialization voltage of the first initialization voltage line VIL1. For another example, the second initialization voltage may be equal to the first initialization voltage. The gate electrode of the seventh transistor T7 may be connected to the fourth gate line GBL, the first electrode thereof may be connected to the fourth node N4, and the second electrode thereof may be connected to the second initialization voltage line VIL2. The first electrode of the seventh transistor T7 may be electrically connected to the first electrode of the light-emitting element ED and the second electrode of the sixth transistor T6 through the fourth node N4. For example, the first electrode of the seventh transistor T7 may be the source electrode while the second electrode may be the drain electrode. It is, however, to be understood that the present disclosure is not limited thereto.

The eighth transistor T8 may be turned on by the fourth gate signal of the fourth gate line GBL to electrically connect the bias voltage line VBL with the first node N1 which is the first electrode of the first transistor T1. The gate electrode of the eighth transistor T8 may be connected to the fourth gate line GBL, the first electrode thereof may be connected to the bias voltage line VBL, and the second electrode thereof may be connected to the first node N1. The second electrode of the eighth transistor T8 may be electrically connected to the first electrode of the first transistor T1, the second electrode of the second transistor T2 and the second electrode of the fifth transistor T5 through the first node N1. For example, the first electrode of the eighth transistor T8 may be the source electrode while the second electrode may be the drain electrode. It is, however, to be understood that the present disclosure is not limited thereto. Optionally, the eighth transistor T8 may be eliminated.

Each of the first transistor T1, the second transistor T2, the fifth transistor T5, the sixth transistor T6, the seventh transistor T7 and the eighth transistor T8 may include a silicon-based semiconductor region. For example, each of the first transistor T1, the second transistor T2, the fifth transistor T5, the sixth transistor T6, the seventh transistor T7 and the eighth transistor T8 may include a semiconductor region made of low-temperature polycrystalline silicon (LTPS). The semiconductor region made of low-temperature polycrystalline silicon may have a high electron mobility and excellent turn-on characteristics. Therefore, the display device 10 includes the first transistor T1, the second transistor T2, the fifth transistor T5, the sixth transistor T6, the seventh transistor T7 and the eighth transistor T8 having excellent turn-on characteristics, so that the plurality of pixels SP can be driven stably and efficiently.

Each of the first transistor T1, the second transistor T2, the fifth transistor T5, the sixth transistor T6, the seventh transistor T7 and the eighth transistor T8 may be a p-type transistor. For example, each of the first transistor T1, the second transistor T2, the fifth transistor T5, the sixth transistor T6, the seventh transistor T7 and the eighth transistor T8 may output the current introduced from the first electrode via the second electrode based on a gate-low voltage applied to the gate electrode.

The third transistor T3 and the fourth transistor T4 may include an oxide-based semiconductor region. For example, each of the third transistor T3 and the fourth transistor T4 may have a coplanar structure in which a gate electrode is disposed above an oxide-based semiconductor region. A transistor having such a coplanar structure has excellent leakage current characteristics and allows for low-frequency driving, thereby reducing power consumption. Accordingly, the display device 10 includes the third transistor T3 and the fourth transistor T4 having good leakage current characteristics, so that it is possible to prevent leakage current from flowing inside the pixels, and to maintain the voltage inside the pixels stably.

Each of the third transistor T3 and the fourth transistors T4 may be an n-type transistor. For example, the third transistor T3 and the fourth transistor T4 may output the current flowing into the first electrode to the second electrode based on a gate-low voltage applied to the gate electrode.

The capacitor C1 may be connected between the third node N3 which is the gate electrode of the first transistor T1 and the supply voltage line VDL. For example, the first capacitor electrode of the capacitor C1 is connected to the third node N3, and the second capacitor electrode of the capacitor C1 is connected to the supply voltage line VDL, so that the potential difference between the supply voltage line VDL and the gate electrode of the first transistor T1 can be held.

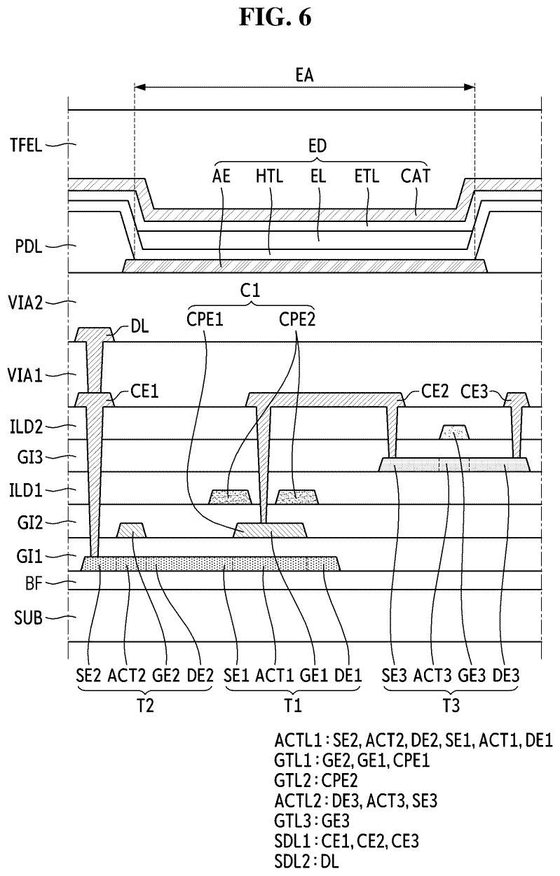

FIG. 6 is a cross-sectional view showing a pixel in a display device according to an embodiment of the present disclosure.

Referring to FIG. 6, a display panel 100 may include a substrate SUB, a buffer layer BF, a first active layer ACTL1, a first gate insulator GI1, a first gate layer GTL1, a second gate insulator GI2, a second gate layer GTL2, a first interlayer dielectric layer ILD1, a second active layer ACTL2, a third gate insulator GI3, a third gate layer GTL3, a second interlayer dielectric layer ILD2, a first source metal layer SDL1, a first via layer VIA1, a second source metal layer SDL2, a second via layer VIA2, a pixel-defining layer PDL, a light-emitting element ED, and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide (PI). For another example, the substrate SUB may include a glass material or a metal material.

The buffer layer BF may be disposed on the substrate SUB. For example, the buffer layer BF may include an inorganic film that can prevent the permeation of air or moisture. For example, the buffer layer BF may include a plurality of inorganic films stacked on one another alternately.

The first active layer ACTL1 may be disposed on the buffer layer BF. The first active layer ACTL1 may include a silicon-based material. For example, the first active layer ACTL1 may be made of low-temperature polycrystalline silicon (LTPS). The first active layer ACTL1 may include a semiconductor region ACT1, a first electrode SE1 and a second electrode DE1 of the first transistor T1, and a semiconductor region ACT2, a first electrode SE2 and a second electrode DE2 of the second transistor T2.

The first gate insulator GIl may be disposed on the first active layer ACTL1. The first gate insulator GI1 may insulate the first active layer ACTL1 from the first gate layer GTL1.

The first gate layer GTL1 may be disposed on the first gate insulator GI1. The first gate layer GTL1 may include a gate electrode GE1 of the first transistor T1, a gate electrode GE2 of the second transistor T2, and a first capacitor electrode CPE1. The gate electrode GE1 of the first transistor T1 may be a portion of the first capacitor electrode CPE1, and the gate electrode GE2 of the second transistor T2 may be a portion of the first gate line GWL.

The second gate insulator GI2 may be disposed on the first gate layer GTL1. The second gate insulator GI2 may insulate the first gate layer GTLI from the second gate layer GTL2.

The second gate layer GTL2 may be disposed on the second gate insulator GI2. The second gate layer GTL2 may include a second capacitor electrode CPE2. The second capacitor electrode CPE2 may overlap with the first capacitor electrode CPE1.

The first interlayer dielectric layer ILD1 may be disposed on the second gate layer GTL2. The first interlayer dielectric layer ILD1 may insulate the second gate layer GTL2 from the second active layer ACTL2.

The second active layer ACTL2 may be disposed on the first interlayer dielectric layer ILD1. The second active layer ACTL2 may include an oxide-based material. The second active layer ACTL2 may include a semiconductor region ACT3, a first electrode DE3 and a second electrode SE3 of the third transistor T3.

The third gate insulator GI3 may be disposed on the second active layer ACTL2. The third gate insulator GI2 may insulate the second active layer ACTL2 from the third gate layer GTL3.

The third gate layer GTL3 may be disposed on the third gate insulator GI3. The third gate layer GTL3 may include a gate electrode GE3 of the third transistor T3. The gate electrode GE3 of the third transistor T3 may be a portion of the second gate line GCL.

The second interlayer dielectric layer ILD2 may be disposed on the third gate layer GTL3. The second interlayer dielectric layer ILD2 may insulate the third gate layer GTL3 from the first source metal layer SDL1.

The first source metal layer SDL1 may be disposed on the second interlayer dielectric layer ILD2. The first source metal layer SDL1 may include first to third connection electrodes CE1, CE2 and CE3. The first connection electrode CE1 may electrically connect the data line DL with the first electrode SE2 of the second transistor T2. The second connection electrode CE2 may electrically connect the first capacitor electrode CPE1 with the second electrode SE3 of the third transistor T3. The third connection electrode CE3 may electrically connect the first electrode DE3 of the third transistor T3 with the second electrode DE1 of the first transistor T1.

The first via layer VIA1 may be disposed on the first source metal layer SDL1. The first via layer VIA1 may insulate the first source metal layer SDL1 from the second source metal layer SDL2. The first via layer VIA1 may have a flat upper surface. The first via layer VIA1 may include an organic insulating material such as polyimide (PI).

The second source metal layer SDL2 may be disposed on the first via layer VIA1. The second source metal layer SDL2 may include the data line DL.

The second via layer VIA2 may be disposed on the second source metal layer SDL2. The second via layer VIA2 may insulate the second source metal layer SDL2 from a pixel electrode AE. The second via layer VIA2 may have a flat upper surface. The second via layer VIA2 may include an organic insulating material such as polyimide (PI).

The pixel-defining layer PDL may be disposed on the second via layer VIA2. The pixel-defining layer PDL may define a plurality of emission areas EA. The pixel-defining layer PDL may include an organic insulating material such as polyimide (PI).

The light-emitting element ED may include the pixel electrode AE, a hole transport layer HTL, an emissive layer EL, an electron transport layer ETL, and a common electrode CAT. The pixel electrode AE may be disposed on the second via layer VIA2. The pixel electrode AE may overlap with one of a plurality of emission areas EA defined by the pixel-defining layer PDL. The pixel electrode AE may receive a driving current from the pixel circuit of the pixel SP.

The hole transport layer HTL may be disposed on the pixel electrode AE in the emission area EA and may be disposed on the pixel-defining layer PDL in the non-emission area. The hole transport layer HTL may not be separately disposed in each of the pixels SP but may be implemented as a common layer across all of the pixels SP.

The emissive layer EL may be disposed on the hole transport layer HTL in the emission area EA. For example, the emissive layer EL may be, but is not limited to, an organic emissive layer made of an organic material.

The electron transport layer ETL may be disposed on the emissive layer EL in the emission area EA and may be disposed on the hole transport layer HTL in the non-emission area. The electron transport layer ETL may not be separately disposed in each of the pixels SP but may be implemented as a common layer across all of the pixels SP.

The common electrode CAT may be disposed on the electron transport layer ETL. For example, the common electrode CAT may be implemented in the form of a common electrode extended across all of the sub-pixels SP. The common electrode CAT may be a transparent electrode and may transmit light. The common electrode CAT may be electrically connected to the low-level voltage line VSL and may receive a low-level voltage, a common voltage, or a cathode voltage.

If the emissive layer EL is an organic light-emitting layer, when the pixel circuit of the pixel SP applies a predetermined voltage to the pixel electrode AE and the common electrode CAT receives a common voltage or cathode voltage, holes may move to the emissive layer EL through the hole transport layer HTL and electrons may move to the emissive layer EL through the electron transport layer ETL, and they may combine in the emissive layer EL to emit light.

The encapsulation layer TFEL may be disposed on the common electrode CAT to cover the light-emitting diodes ED. The encapsulation layer TFEL may include at least one inorganic film to prevent permeation of oxygen or moisture into the light-emitting elements ED. The encapsulation layer TFEL may include at least one organic film to protect the light-emitting elements ED from particles such as dust.

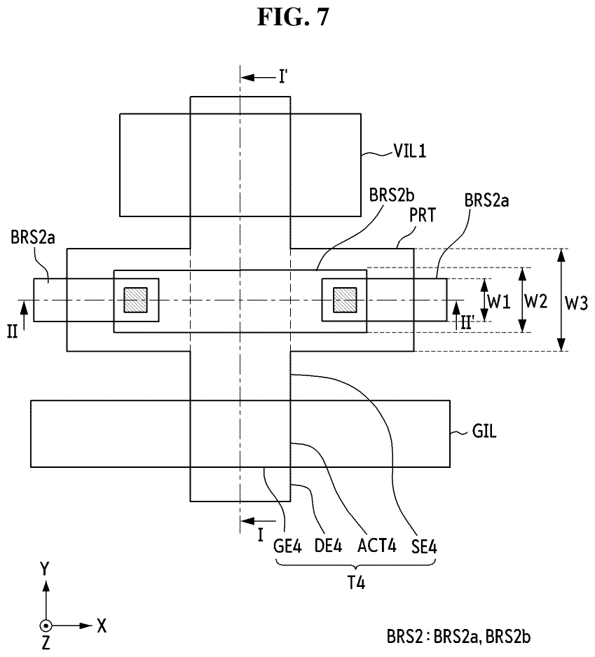

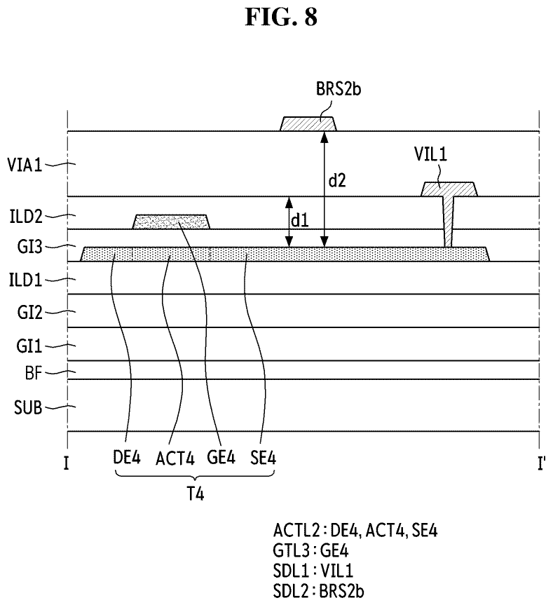

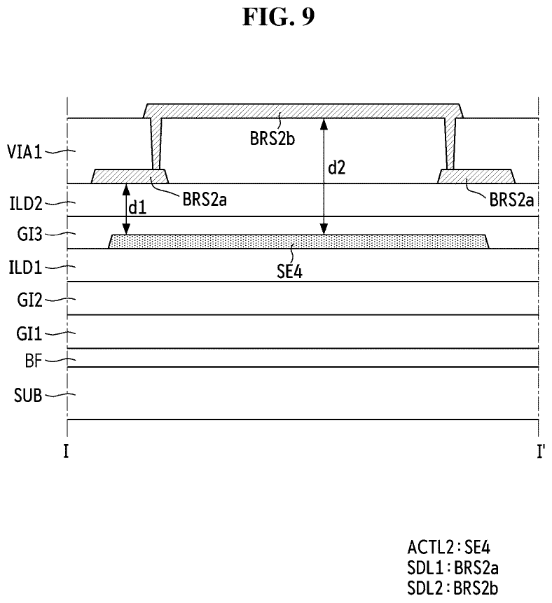

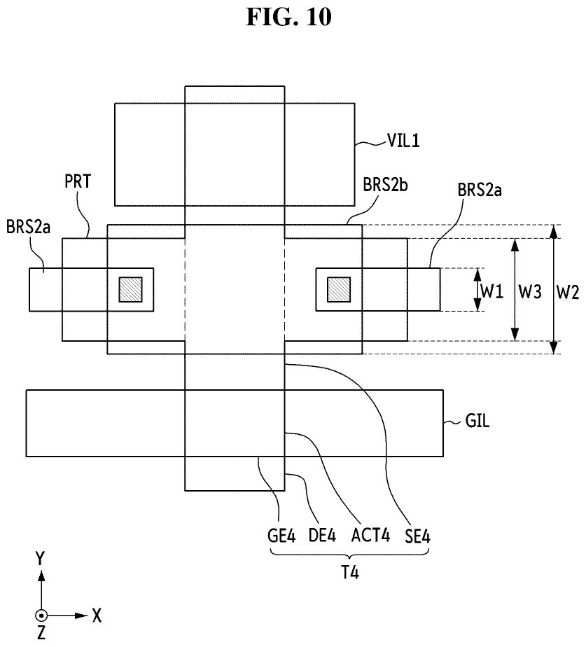

FIG. 7 is a layout diagram showing a part of a pixel according to an embodiment. FIG. 8 is a cross-sectional view, taken along line I-I′ of FIG. 7. FIG. 9 is a cross-sectional view, taken along line II-II′ of FIG. 7.

Referring to FIGS. 7 to 9, some of the plurality of pixels SP may overlap with the second bridge line BRS2.

The fourth transistor T4 may include a semiconductor region ACT4, a gate electrode GE4, a first electrode DE4, and a second electrode SE4. The semiconductor region ACT4, the first electrode DE4 and the second electrode SE4 of the fourth transistor T4 may be disposed in the second active layer ACTL2, and the gate electrode GE4 may be disposed in the third gate layer GTL3. The gate electrode GE4 of the fourth transistor T4 may overlap with the semiconductor region ACT4.

The third gate line GIL may be disposed in the third gate layer GTL3 and may be extended in the x-axis direction. The gate electrode GE4 of the fourth transistor T4 may be a portion of the third gate line GIL.

The second electrode SE4 of the fourth transistor T4 may be extended in the y-axis direction and may include a protrusion PRT extended in the x-axis direction. The second electrode SE4 of the fourth transistor T4 may be connected to the first initialization voltage line VIL1 of the first source metal layer SDL1 and may receive the first initialization voltage from the first initialization voltage line VIL1.

The second electrode SE4 of the fourth transistor T4 may overlap with the second bridge line BRS2 shown in FIG. 3. The second bridge line BRS2 may be extended in the x-axis direction and electrically connect between the first and third bridge lines BRS1 and BRS3. The second bridge line BRS2 may be disposed between the first initialization voltage line VILI and the third gate line GIL. The second bridge line BRS2 may be disposed between the first initialization voltage line VILI and the fourth transistor T4. The second bridge line BRS2 may include first and second portions BRS2a and BRS2b.

The first portions BRS2a of the second bridge line BRS2 may be disposed in the first source metal layer SDL1 and may be extended in the x-axis direction. The second portion BRS2b of the second bridge line BRS2 may be disposed in the second source metal layer SDL2 and may be extended in the x-axis direction. The second portion BRS2b of the second bridge line BRS2 may electrically connect between the first portions BRS2a spaced apart from each other in the x-axis direction. The first portion BRS2a of the second bridge line BRS2 may have a first width W1 in the y-axis direction, and the second portion BRS2b of the second bridge line BRS2 may have a second width W2 in the y-axis direction. The protrusion PRT of the second electrode SE4 of the fourth transistor T4 may have a third width W3 in the y-axis direction. The second width W2 may be greater than the first width W1, and the third width W3 may be greater than the second width W2.

The second portion BRS2b of the second bridge line BRS2 may overlap with the second electrode SE4 of the fourth transistor T4 excluding the protrusion PRT. The second electrode SE4 of the fourth transistor T4 and the first source metal layer SDL1 may be spaced apart from each other by a first distance d1, and the second electrode SE4 of the fourth transistor T4 and the second source metal layer SDL2 may be spaced apart from each other by a second distance d2. The first distance d1 may be determined depending on the thicknesses of the second active layer ACTL2, the third gate insulator GI3 and the second interlayer dielectric layer ILD2. The second distance d2 may be determined depending on the thicknesses of the second active layer ACTL2, third gate insulator GI3, the second interlayer dielectric layer ILD2 and the first via layer VIA1. The thickness of the second interlayer dielectric layer ILD2 may be greater than the thickness of the third gate insulator GI3, and the thickness of the first via layer VIA1 may be greater than the thickness of the second interlayer dielectric layer ILD2.

When the fourth transistor T4 is turned on, the first initialization voltage may be supplied from the first initialization voltage line VILI to the first electrode DE4 of the fourth transistor T4. That is to say, the initialization voltage may be supplied through the path along line I-I′ in FIG. 7. For example, if all portions of the second bridge line BRS2 are disposed in the first source metal layer SDL1, the second bridge line BRS2 of the first source metal layer SDL1 may be disposed on the path via which the first initialization voltage is applied, and a parasitic transistor having the second bridge line BRS2 as the gate electrode may be formed. When this happens, the parasitic transistor may act as a resistance and deteriorate the initialization function for the first node N1, which is the gate electrode GE1 of the first transistor T1. In addition, Mura or poor brightness may occur on the display panel 100.

The display device 10 includes the second portion BRS2b of the second bridge line BRS2, the second bridge line BRS2 can be spaced as much as possible from the second electrode SE4 of the fourth transistor T4 on the path through which the first initialization voltage is applied. As the second portion BRS2b of the second bridge line BRS2 and the second electrode SE4 of the fourth transistor T4 are spaced apart from each other by the second distance d2, it is possible to prevent the formation of the parasitic transistor compared to the structure in which the second bridge line BRS2 is spaced apart from the second electrode SE4 of the fourth transistor T4 by the first distance d1. Accordingly, in the display device 10, the first initialization voltage can be properly applied to the gate electrode GE1 of the first transistor T1, and Mura or poor brightness of the display panel 100 can be prevented.

FIG. 10 is a layout diagram showing a part of a pixel according to an embodiment. A pixel of FIG. 10 is substantially identical to the pixel of FIG. 7 except for a second portion BRS2b of a second bridge line BRS2; and, therefore, the redundant description will be omitted.

Referring to FIG. 10, the second electrode SE4 of the fourth transistor T4 may overlap with the second bridge line BRS2 shown in FIG. 3. The second bridge line BRS2 may be extended in the x-axis direction and electrically connect between the first and third bridge lines BRS1 and BRS3. The second bridge line BRS2 may include first and second portions BRS2a and BRS2b.

The first portion BRS2a of the second bridge line BRS2 may be disposed in the first source metal layer SDL1 and may be extended in the x-axis direction. The second portion BRS2b of the second bridge line BRS2 may be disposed in the second source metal layer SDL2 and may be extended in the x-axis direction. The second portion BRS2b of the second bridge line BRS2 may electrically connect between the first portions BRS2a spaced apart from each other in the x-axis direction. The first portions BRS2a of the second bridge line BRS2 may have a first width W1 in the y-axis direction, and the second portion BRS2b of the second bridge line BRS2 may have a second width W2 in the y-axis direction. The protrusion PRT of the second electrode SE4 of the fourth transistor T4 may have a third width W3 in the y-axis direction. The third width W3 may be greater than the first width W1, and the second width W2 may be greater than the third width W3.

The second width W2 of the second portion BRS2b of the second bridge line BRS2 of FIG. 10 may be greater than the second width W2 of the second portion BRS2b of the second bridge line BRS2 of FIG. 7. The second portion BRS2b of the second bridge line BRS2 of FIG. 10 has a relatively large width, thereby reducing the line resistance.

The current disclosure should not be construed as being limited to the embodiments set forth herein. Rather, these embodiments are provided so that this disclosure will be thorough and complete and will fully convey the concept of the present disclosure to those skilled in the art.

While the current disclosure has been particularly shown and described with reference to some embodiments thereof, it will be understood by one of ordinary skill in the art that various changes in form and detail may be made therein without departing from the spirit and scope of the current disclosure as defined by the following claims.

What is claimed is:

1. A display device comprising:
a display area comprising a plurality of pixels;
a display driver disposed outside the display area to apply a data voltage;
a plurality of data lines for applying the data voltage to the plurality of pixels; and
a bridge line electrically connecting some of the data lines with the display driver,
wherein the bridge line comprises:
a first bridge line extended from the display driver in a first direction; and
a second bridge line connected to the first bridge line and extended in a second direction intersecting the first direction,
wherein the second bridge line comprises:
a plurality of first portions extended in the second direction and spaced apart from each other in the second direction; and
a second portion disposed on the first portions and electrically connecting the first portions.

2. The display device of claim 1, further comprising:
a first initialization voltage line for applying a first initialization voltage to the plurality of pixels,
wherein at least one pixel among the plurality of pixels comprises:
a light-emitting element disposed on a substrate;
a first transistor configured to control a driving current flowing through the light-emitting element;
a second transistor configured to supply a data voltage to a first electrode of the first transistor;
a third transistor configured to electrically connect a second electrode of the first transistor with a gate electrode of the first transistor; and
a fourth transistor configured to electrically connect the gate electrode of the first transistor with the first initialization voltage line.

3. The display device of claim 2, wherein a first electrode of the fourth transistor is electrically connected to the gate electrode of the first transistor, and wherein a second electrode of the fourth transistor overlaps with the second portion of the second bridge line.

4. The display device of claim 2, further comprising:
a first gate line for supplying a first gate signal to the second transistor;
a second gate line for supplying a second gate signal to the third transistor; and
a third gate line for supplying a third gate signal to the fourth transistor.

5. The display device of claim 4, wherein the second portion of the second bridge line is disposed between the first initialization voltage line and the third gate line.

6. The display device of claim 3, wherein the second electrode of the fourth transistor comprises a protrusion protruding in the second direction, and
wherein a width of the second portion of the second bridge line in the first direction is smaller than a width of the protrusion in the first direction.

7. The display device of claim 3, wherein the second electrode of the fourth transistor comprises a protrusion protruding in the second direction, and
wherein a width of the second portion of the second bridge line in the first direction is greater than a width of the protrusion in the first direction.

8. The display device of claim 2, further comprising:
a first active layer comprising semiconductor regions of the first and second transistors;
a first gate layer disposed on the first active layer;
a second gate layer disposed on the first gate layer;
a second active layer comprising semiconductor regions of the third and fourth transistors;
a third gate layer disposed on the second active layer;
a first source metal layer disposed on the third gate layer and comprising the first portions of the second bridge line; and
a second source metal layer disposed on the first source metal layer and comprising the second portion of the second bridge line.

9. The display device of claim 2, further comprising:
a driving voltage line for applying a driving voltage to the plurality of pixels; and
a second initialization voltage line for applying a second initialization voltage to the plurality of pixels,
wherein the at least one pixel further comprises:
a fifth transistor configured to electrically connect the driving voltage line with the first electrode of the first transistor;
a sixth transistor configured to electrically connect the second electrode of the first transistor with a first electrode of the light-emitting element; and
a seventh transistor configured to electrically connect the first electrode of the light-emitting element with the second initialization voltage line.

10. The display device of claim 9, further comprising:
a bias voltage line for applying a bias voltage,
wherein the at least one pixel further comprises:
an eighth transistor configured to electrically connect the bias voltage line with the first electrode of the first transistor.

11. A display device comprising:
first and second pixels each comprising a light-emitting element;
a display driver configured to apply data voltage to the first and second pixels;
a first data line connected to the display driver to apply the data voltage to the first pixel;
a second data line for apply the data voltage to the second pixel; and
a bridge line electrically connecting the display driver and the second data line,
wherein the bridge line comprises:
a first bridge line extended from the display driver in a first direction; and
a second bridge line connected to the first bridge line and extended in a second direction intersecting the first direction to overlap with the first pixel, and
wherein the second bridge line comprises:
a plurality of first portions extended in the second direction and spaced apart from each other in the second direction; and
a second portion disposed on the first portions and electrically connecting the first portions.

12. The display device of claim 11, wherein the bridge line further comprises: a third bridge line connecting the second bridge line and the second data line and extended in the first direction.

13. The display device of claim 11, further comprising:
a first active layer disposed on a substrate and comprising a first material;
a first gate layer disposed on the first active layer;
a second gate layer disposed on the first gate layer;
a second active layer disposed on the second gate layer and comprising a second material different from the first material;
a third gate layer disposed on the second active layer;
a first source metal layer disposed on the third gate layer and comprising the first portions of the second bridge line; and
a second source metal layer disposed on the first source metal layer and comprising the second portion of the second bridge line.

14. The display device of claim 13, further comprising:
a first initialization voltage line for applying a first initialization voltage to the first and second pixels,
wherein the first pixel comprises:
a first transistor configured to control a driving current flowing through the light-emitting element;
a second transistor electrically connecting a first electrode of the first transistor with the first data line;
a third transistor electrically connecting a second electrode of the first transistor with a gate electrode of the first transistor; and
a fourth transistor electrically connecting the gate electrode of the first transistor with the first initialization voltage line.

15. The display device of claim 14, wherein the second portion of the second bridge line is disposed between the fourth transistor and the first initialization voltage line.

16. The display device of claim 14, wherein semiconductor regions of the first and second transistors are disposed in the first active layer, and semiconductor regions of the third and fourth transistors are disposed in the second active layer.

17. The display device of claim 14, further comprising:
a first gate line disposed in the first gate layer to supply a first gate signal to the second transistor;
a second gate line disposed in the third gate layer to supply a second gate signal to the third transistor; and
a third gate line disposed in the third gate layer to supply a third gate signal to the fourth transistor.

18. The display device of claim 17, wherein the second portion of the second bridge line is disposed between the first initialization voltage line and the third gate line.

19. A display device comprising:
a display driver configured to apply data voltage;
first and second data lines extended in a first direction and electrically connected to the display driver;
a first initialization voltage line for applying a first initialization voltage;
a light-emitting element emitting light;
a first transistor configured to control a driving current flowing through the light-emitting element;
a second transistor configured to electrically connect the first data line with a first electrode of the first transistor;
a third transistor configured to electrically connect a second electrode of the first transistor with a gate electrode of the first transistor;
a fourth transistor configured to electrically connect the gate electrode of the first transistor with the first initialization voltage line;
a bridge line electrically connecting the display driver with the second data line and overlapping with the fourth transistor, and
wherein the bridge line comprises:
a plurality of first portions extended in a second direction intersecting the first direction and spaced apart from each other in the second direction; and
a second portion disposed on the first portions and electrically connecting the first portions.

20. The display device of claim 19, further comprising:
a first active layer comprising semiconductor regions of the first and second transistors;
a first gate layer disposed on the first active layer;
a second gate layer disposed on the first gate layer;
a second active layer comprising semiconductor regions of the third and fourth transistors;
a third gate layer disposed on the second active layer;
a first source metal layer disposed on the third gate layer and comprising the first portions of the bridge line; and
a second source metal layer disposed on the first source metal layer and comprising the second portion of the bridge line.

21. The display device of claim 1, wherein the display device is part of one of a mobile phone, a smart phone, a tablet PC, a mobile communications terminal, an electronic notebook, an electronic book, a portable multimedia player, a navigation device, an ultra-mobile PC, a television, a laptop computer, a monitor, an electronic billboard, an Internet of Things, a smart watch, a watch phone, a glasses-type display, and a head-mounted display device.
